(19) United States
(12) Patent Application Publication
(10) Pub. No.: US 2007/0273280 A1
(43) Pub. Date: Nov. 29, 2007

(54) Organic light emitting device and organic electronic device

(76) Inventors: Sang-Yeol Kim, Yongin-si (KR); Jong-Jin Park, Yongin-si (KR); Lyong-Sun Pu, Yongin-si (KR); Joon-Yong Park, Yongin-si (KR); Young-Mok Son, Yongin-si (KR); Sung-Hun Lee, Yongin-si (KR); Mu-Gyeom Kim, Yongin-si (KR); Tae-Woo Lee, Yongin-si (KR)

Correspondence Address: Robert E. Bushnell, Suite 300, 1522 K Street, N.W., Washington, DC, 20005-1202, US

(21) Appl. No.: 11/730,864

(22) Filed: Apr. 4, 2007

(30) Foreign Application Priority Data
May 25, 2006 (KR) 10-2006-0047221

(51) Int. Cl. H05B 33/22; H01L 51/50

(52) U.S. Cl. 313/509; 313/503; 313/506

(57) ABSTRACT

An organic light emitting device has a structure in which the penetration of harmful materials into an inner functional layer is blocked to prevent the degradation of the performance of the organic light emitting device and an organic electronic device includes such an organic light emitting device. The organic light emitting device includes an insulating substrate; a light emitting unit arranged on the insulating substrate and including a first electrode layer to inject holes, a second electrode layer to inject electrons, and an active layer interposed between the first and second electrode layers to emit light by recombining the holes and electrons; and a passivation layer including alternately arranged barrier layers and buffer layers to seal the light emitting unit from an external atmosphere, each barrier layer including at least one material selected from a group consisting of an activated metal oxide, an activated metal nitride, or an activated metal oxynitride, and each buffer layer being of a polymer organic material.

### CLAIM OF PRIORITY

This application makes reference to, incorporates the same herein, and claims all benefits accruing under 35 U.S.C. § 119 from an application for ORGANIC LIGHT EMITTING DEVICE AND ORGANIC ELECTRONIC DEVICE earlier filed in the Korean Intellectual Property Office on 25 May 2006 and there duly assigned Serial No. 10-2006-0047221.

### BACKGROUND OF THE INVENTION

1. Field of the Invention

The present invention relates to an organic light emitting device and an organic electronic device, and more particularly, the present invention relates to an organic light emitting device having a structure in which the penetration of a harmful element into an inner functional layer is shielded in order to prevent the degradation of the performance of the organic light emitting device and an organic electronic device.

2. Description of the Related Art

FIG. 1 is a vertical cross-sectional view of an organic light emitting device. Referring to FIG. 1, a first electrode layer 21 formed of Indium Tin Oxide (ITO) for injecting holes, an organic thin film layer 23 for emitting light by recombining holes and electrons, and a second electrode layer 25 for injecting electrons are sequentially formed on a substrate 10. In the organic thin film layer 23, light is generated by recombining holes and electrons that are respectively supplied from the first electrode layer 21 and the second electrode layer 25. For this purpose, the first electrode layer 21 may be formed of a material having a large work function and the second electrode layer 25 may be formed of a material having a small work function. The second electrode layer 25 readily corrodes or oxidizes by reacting with external oxygen due to its characteristics of high activity and chemical instability. The organic thin film layer 23 also has problems of degrading light emission characteristics by changing in terms of structure through crystallization when moisture or oxygen penetrates the organic thin film layer 23.

Therefore, to prevent the penetration of external harmful materials into a light emitting unit 20 that includes the first and second electrodes 21 and 25 and the organic thin film layer 23, the light emitting unit 20 is sealed using a sealing can 30 formed of metal or glass. The sealing can 30 is bonded to the first electrode layer 21 using a resin sealant 50, for example, a UV adhesive, and a moisture absorbent 40 composed of barium oxide (BaO) is disposed on an inner-side of the sealing can 30.

However, the sealing can 30 increases the weight and volume of a display device, and is a limiting factor for making a light-weight, thin, small display device. Also, the sealing can 30 reduces the transmittance of light emitted from the light emitting unit 20 in the upper direction. In particular, the moisture absorbent 40 that is attached to the sealing can 30 by an adhesive tape (not shown) is also another cause of reducing transmittance of light in the upper direction.

When the can type sealing method is applied to large-scale display devices, a deformation due to a twist can occur on the sealing can 30 that has a weak supporting structure to begin with. Therefore, there is a structural limitation in using the can type sealing method on large scale display devices that are 2 inches or more in size. In general, the thickness of the sealing can 30 is limited to a predetermined range in consideration of the light transmittance and weight of the organic light emitting device. Therefore, the resin sealant 50 cannot be formed to a thickness sufficient to fix the sealing can 30. Thus, external harmful materials penetrate the inner side of the organic light emitting device through the resin sealant 50. Furthermore, impure gases are generated by vaporizing a solvent during a hardening process of the resin sealant 50, and the impure gases can affect the display function by entering inside of the organic light emitting device. Also, thermal stress occurs on the resin sealant 50 due to the thermal expansion of the sealing can 30, and thus, an additional buffer layer (not shown) for releasing the thermal stress is needed.

Also, the attaching of the sealing can 30 and the mounting of the moisture absorbent 40 require additional manpower, thereby reducing productivity and increasing manufacturing costs. In particular, the attachment of the sealing can 30 and the mounting of the moisture absorbent 40 are not suitable to apply an in-line-process for mass production due to its manufacturing process characteristics, thereby causing process delays or increasing manufacturing costs.

### SUMMARY OF THE INVENTION

The present invention provides an organic light emitting device having a structure in which the penetration of harmful elements into an inner functional layer is shielded to prevent the degradation in performance of the organic light emitting device and an organic electronic device including the organic light emitting device.

The present invention also provides an organic light emitting device that is thin, light-weight and flexible and an organic electronic device including the organic light emitting device.

The present invention also provides an organic light emitting device that reduces manufacturing costs through an in-line-automatic process and an organic electronic device including the organic light emitting device.

According to one aspect of the present invention, an organic light emitting device is provided including: an insulating substrate; a light emitting unit arranged on the insulating substrate and including a first electrode layer to inject holes, a second electrode layer inject electrons, and an active layer interposed between the first and second electrode layers to emit light by recombining the holes and electrons; and a passivation layer including a plurality of alternately arranged barrier layers and buffer layers to seal the light emitting unit from an external atmosphere, each barrier layer including at least one material selected from a group consisting of an activated metal oxide, an activated metal nitride, or an activated metal oxynitride, and each buffer layer including either a polymer organic material or small molecule organic material.

The activated metal oxide preferably includes a metal oxide in an activated unstable state derived from a stable metal oxide due to a deficiency in oxygen atoms.

The activated metal nitride preferably includes a metal nitride in an activated unstable state derived from a stable metal nitride due to a deficiency in nitrogen atoms.

The activated metal oxynitride preferably includes a metal oxynitride in an activated unstable state derived from a stable metal oxynitride due to a deficiency in oxygen and/or nitrogen atoms.

The activated metal oxide preferably includes an oxide selected from a group consisting of Al₂O_{X}(1<X<3), BaO_{X}(0<X<1), In₂O_{X}(1<X<3), TiO_{X}(1<X<2), MgO_{X}(0<X<1), GeO_{X}(0<X<1), CaO_{X}(0<X<2), SrO_{X}(0<X<1), Y₂O_{X}(0<X<3), HfO_{X}(0<X<2), ZrO_{X}(0<X<2), MoO_{X}(0<X<3), and V₂O_{X}(0<X<5).

The activated metal nitride preferably includes either AlN_{X}(0<X<1) or GaN_{X}(0<X<1).

The activated metal oxynitride preferably includes SiO_{X}N_{Y}(0<X<2)(0<Y<2).

Each buffer layer is preferably formed by either a vapor deposition polymerization method or vapor deposition method. Each buffer layer preferably includes a small molecule organic material or a polymer organic material selected from a group consisting of polyurea, polyimide, and polyamide.

The organic light emitting device preferably further includes an additional passivation layer arranged on a lower surface of the insulating substrate.

According to another aspect of the present invention, an organic electronic device is provided including: an insulating substrate; a plurality of electrodes arranged on the insulating substrate; a conductive path including an organic semiconductor layer arranged across at least a portion of the plurality of electrodes; and a passivation layer including a plurality of alternately arranged barrier layers and buffer layers to seal the organic semiconductor layer from an external atmosphere, each barrier layer including at least one material selected from a group consisting of an activated metal oxide, an activated metal nitride, or an activated metal oxynitride, and each buffer layer including a polymer organic material.

A gate electrode, an organic insulating film covering the gate electrode, and a source electrode and a drain electrode arranged on the organic insulating film are preferably sequentially arranged on the insulating substrate, and the organic semiconductor layer is preferably arranged across the source electrode and the drain electrode and a portion of the organic insulating film.

The activated metal oxide preferably includes a metal oxide in an activated unstable state derived from a stable metal oxide due to a deficiency in oxygen atoms.

The activated metal nitride preferably includes a metal nitride in an activated unstable state derived from a stable metal nitride due to a deficiency in nitrogen atoms.

The activated metal oxynitride preferably includes a metal oxynitride in an activated unstable state derived from a stable metal oxynitride due to a deficiency in oxygen and/or nitrogen atoms.

The activated metal oxide preferably includes an oxide selected from a group consisting of Al₂O_{X}(1<X<3), BaO_{X}(0<X<1), In₂O_{X}(1<X<3), TiO_{X}(1<X<2), MgO_{X}(0<X<1), GeO_{X}(0<X<1), CaO_{X}(0<X<2), SrO_{X}(0<X<1), Y₂O_{X}(0<X<3), HfO_{X}(0<X<2), ZrO_{X}(0<X<2), MoO_{X}(0<X<3), and V₂O_{X}(0<X<5).

The activated metal nitride preferably includes either AlN_{X}(0<X<1) or GaN_{X}(0<X<1).

The activated metal oxynitride preferably includes SiO_{X}N_{Y}(0<X<2)(0<Y<2).

Each buffer layer is preferably formed by a vapor deposition polymerization method or vapor deposition method. Each buffer layer preferably includes a small molecule organic material or a polymer organic material selected from a group consisting of polyurea, polyimide, and polyamide.

The organic electronic device preferably further includes an additional passivation layer arranged on a lower surface of the insulating substrate.

### BRIEF DESCRIPTION OF THE DRAWINGS

A more complete appreciation of the present invention and many of the attendant advantages thereof, will be readily apparent as the present invention becomes better understood by reference to the following detailed description when considered in conjunction with the accompanying drawings in which like reference symbols indicate the same or similar components, wherein:

FIG. 1 is a vertical cross-sectional view of an organic light emitting device;

FIG. 2 is a vertical cross-sectional view of an organic light emitting device according to an embodiment of the present invention;

FIG. 3 is a graph of the variations of luminance according to time as the result of experiments to confirm a harmful material shielding effect in a comparative example and an in experimental embodiment, according to an embodiment of the present invention;

FIG. 4 is a view of the steps in fabricating an organic light emitting device according to an embodiment of the present invention; and

FIG. 5 is a vertical cross-sectional view of an organic light emitting device according to another embodiment of the present invention.

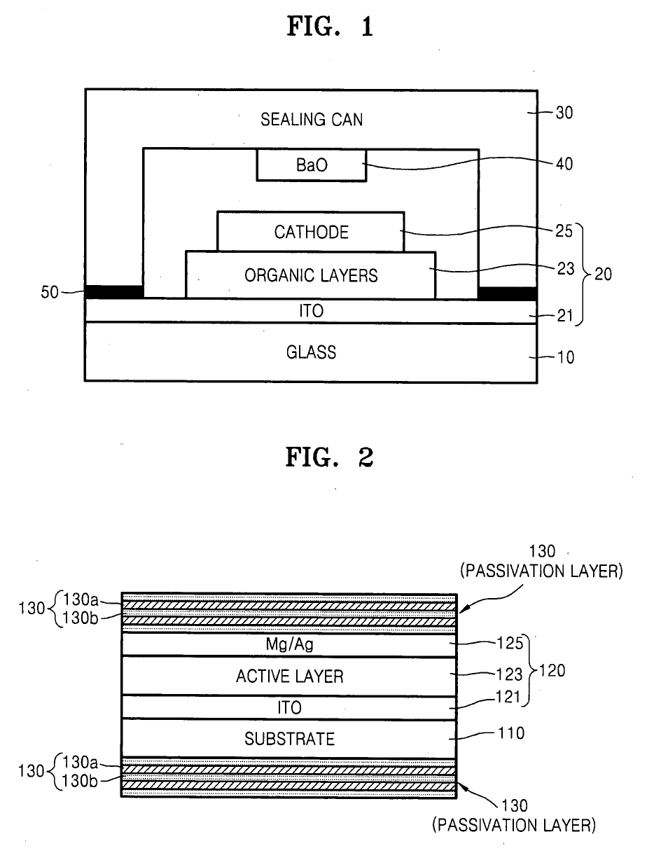

### DETAILED DESCRIPTION OF THE INVENTION

The present invention is described more fully below with reference to the accompanying drawings in which exemplary embodiments of the present invention are shown.

FIG. 2 is a vertical cross-sectional view of an organic light emitting device according to an embodiment of the present invention.

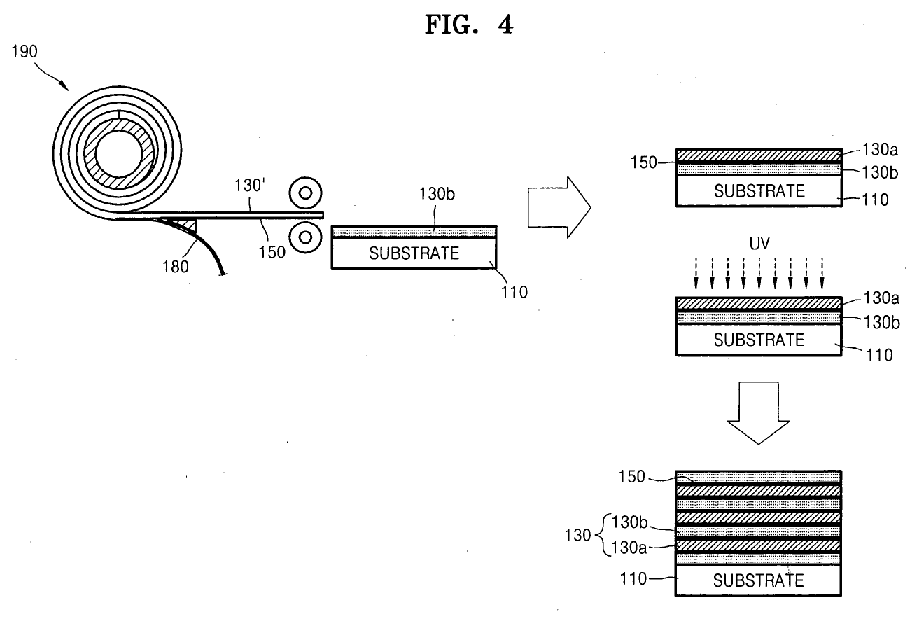

Referring to FIG. 2 and FIG. 4, the organic light emitting device includes an insulating substrate 110, a light emitting unit 120 formed on the insulating substrate 110, and a passivation layer 130 that seals the light emitting unit 120 to protect the light emitting unit 120 from harmful materials. The insulating substrate 110 can be formed of a hard material, such as glass, stainless steel, or aluminum, or alternatively, can be formed of a soft material, such as Polyethylene Terephthalate (PET), Polyethylene Naphthalate (PEN), Polyether Sulfone (PES), Polyimide, Polypropylene, cellophane, PVC, etc. in order to have flexibility.

The light emitting unit 120 displays a predetermined image by emitting red, green, and blue light according to a current flow, and includes a first electrode layer 121 that functions as an anode to inject holes, a second electrode layer 125 that functions as a cathode to injects electron, and an active layer 123 that is interposed between the first and second electrode layers 121 and 125 and generates light by recombining the holes and electrons. The first electrode layer 121 may be formed of a material having a large work function, for example, transparent ITO. The second electrode layer 125 may be formed of a material having a small work function, for example, by depositing Mg/Ag, Mg, Al, or an alloy of these metals. The active layer 123 interposed between the first and second electrode layers 121 and 125 can be formed of a small molecular weight organic film or a polymer organic film. If the active layer 123 is formed of a small molecular weight organic film, the active layer 123 can be formed by stacking a Hole Injection Layer (HIL), a Hole Transport Layer (HTL), an organic Emitting Material Layer (EML), an Electron Transport Layer (ETL), or an Electron Injection Layer (EIL). If the active layer 123 is formed of a polymer organic film, the active layer 123 usually has a structure in which the HTL and the EML are included. The structure of the active layer 123 is not limited thereto, that is, the active layer 123 can be a single layer EML structure, a double layer HTL/EML structure, or a double layer EML/ETL structure.

The passivation layer 130 having a multiple layer structure in which a plurality of barrier layers 130a and a buffer layer 130b are stacked one after the other to prevent the penetration of harmful materials from the air into the light emitting unit 120 is formed on the light emitting unit 120. The passivation layer 130 is formed by alternately stacking the barrier layer 130a and the buffer layer 130b, and may include at least two layers of thin films to ensure the minimum blocking efficiency with respect to the external harmful materials.

The blocking of impurities is mainly achieved by the barrier layer 130a. The barrier layer 130a can be formed of an activated metal oxide, an activated metal nitride, or an activated metal oxynitride. The activated metal oxide denotes a metal oxide in an activated unstable state derived from a stable metal oxide due to a deficiency of an oxygen atom. More specifically, examples of the activated metal oxide are Al₂O_{X}(1<X<3), BaO_{X}(0<X<1), In₂O_{X}(1<X<3), TiO_{X}(1<X<2), MgO_{X}(0<X<1), GeO_{X}(0<X<1), CaO_{X}(0<X<2), SrO_{X}(0<X<1), Y₂O_{X}(0<X<3), HfO_{X}(0<X<2), ZrO_{X}(0<X<2), MoO_{X}(0<X<3), and V₂O_{X}(0<X<5). The activated metal nitride denotes a metal nitride in an activated unstable state derived from a stable metal nitride due to a deficiency in a nitrogen atom. More specifically, some examples of the activated metal nitride are, AlN_{X}(0<X<1) and GaN_{X}(0<X<1). Also, the activated metal oxynitride denotes a metal oxynitride in an activated unstable state derived from a stable metal oxynitride due to a deficiency in an oxygen and/or nitrogen atom. More specifically, an example of the activated metal oxynitride is SiO_{X}N_{Y}(0<X<2)(0<Y<2). Hereinafter, the activated metal oxide, the activated metal nitride, and the activated metal oxynitride will be commonly called the activated metal oxynitride. The activated metal oxynitride, while it stabilizes on its own, functions to absorb impurities through a chemical reaction with the oxygen and/or nitrogen that penetrate into the organic light emitting device. The barrier layer 130a can be formed of an oxide, a nitride, or an oxynitride of 2A, 3A, 4A, 3B, or 4B family metal. However, the present invention is not limited to these metals.

The buffer layer 130b can be formed of a polymer organic material or a small molecule organic material and is interposed between the barrier layers 130a. The buffer layer 130b strengthens the barrier layer 130a that is relatively weak, prevents the barrier layer 130a from being damaged because of brittleness, and provides a better condition for forming the barrier layer 130a so that the passivation layer 130 can be formed to be more than a predetermined thickness. For example, the buffer layer 130b can be formed by a vapor deposition polymerization method in which a polymer organic film is obtained by a polymerization reaction after a precursor material is deposited by vacuum evaporation on a target material. Otherwise, the buffer layer 130b can be formed by a vapor deposition method in which a small molecule organic film is obtained. The polymer organic materials are, for example, polyurea, polyimide, and polyamide. The buffer layer 130b can also be formed by polymerization methods using conventional thermal heating, using a laser or a heat bar, or using an electromagnetic induction heating or ultra sonic friction besides the vapor deposition polymerization method. The polymerization method of forming the buffer layer 130b can be appropriately selected according to the material for forming the buffer layer 130b.

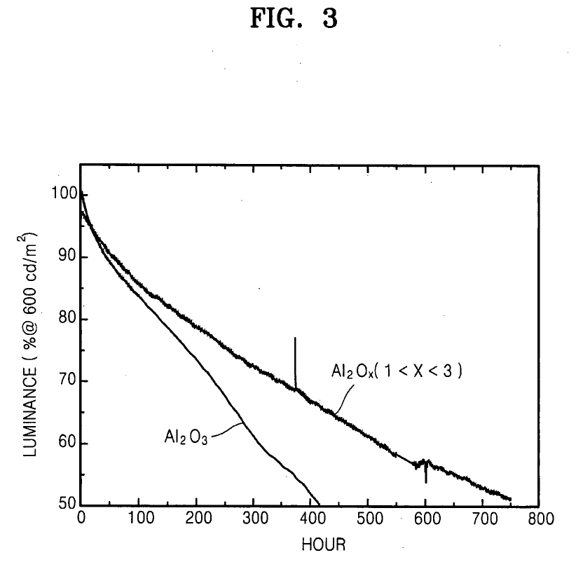

FIG. 3 is a graph of the variations of luminance according to time as the result of experiments to confirm a harmful material shielding effect in a comparative example and an in experimental embodiment, according to an embodiment of the present invention.

In FIG. 3, an experimental result confirms the effects of the present invention. The horizontal axis represents time (hours), and the vertical axis represents luminance. The luminance is expressed in relative percentage with respect to 600 cd/m². In the current experiment, the luminance is compared when the barrier layer 130a is formed of Al₂O₃ and Al₂O_{X}(1<X<3). As seen from the experiment result, the barrier layer 130a formed of Al₂O₃ has a relatively steep slope and shows rapidly decreasing luminance. However, the barrier layer 130a formed of Al₂O_{X}(1<X<3) has a relatively smooth slope and shows slowly decreasing luminance. This is because that Al₂O_{X}(1<X<3) is in an activated state in which oxygen lacks from a stable oxide state of Al₂O₃, and as a result, the Al₂O_{X}(1<X<3) can protect the light emitting unit 120 from the harmful materials by absorbing penetrating oxygen from the outside.

The passivation layer 130 may be formed not only on an upper surface of the light emitting unit 120 that is an element that is to be protected, but also on a lower surface of the insulating substrate 110 in order to block the penetration of harmful materials. The passivation layer 130 formed on the lower surface of the insulating substrate 110 has substantially the same configuration as the passivation layer 130 formed on the upper surface of the light emitting unit 120, and accordingly, includes a plurality of barrier layers 130a and buffer layers 130b that are alternately stacked. Therefore, the descriptions of the barrier layer 130a and the buffer layer 130b have not been repeated.

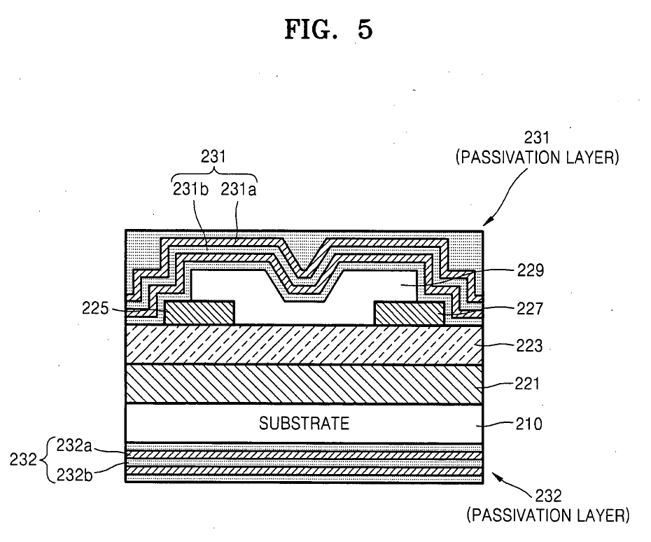

FIG. 5 is a vertical cross-sectional view of an organic electronic device according to another embodiment of the present invention. In FIG. 4, an Organic Thin Film Transistor (OTFT) is depicted as an example of the organic electronic device. The organic electronic device includes a gate electrode 221 formed on a predetermined region of an insulating substrate 210, an organic insulating film 223 that covers the gate electrode 221 to insulate the gate electrode 221, a source electrode 225 and a drain electrode 227 formed on the organic insulating film 223, an organic semiconductor layer 229 formed on the organic insulating film 223 to connect the source electrode 225 to the drain electrode 227, and a passivation layer 231 formed on the organic semiconductor layer 229.

The insulating substrate 210 supports the organic electronic device, and can be formed of a glass material or a flexible polymer material. The gate electrode 221 formed on the insulating substrate 210 can be formed of a conventional metal, such as Au, Ag, Al, Cu, or Ni. The organic insulating film 223 that insulates the gate electrode 221 by burying the gate electrode 221 is formed on the insulating substrate 210, and can be formed of Polyvinylpyrolidone (PVP), polyimide, Benzocyclobutene (BCB), and photoacryl.

The source electrode 225 and the drain electrode 227 are formed on predetermined regions on the organic insulating film 223, and the source electrode 225 and the drain electrode 227 can be formed of a metal electrode material similar to the gate electrode 221. The organic semiconductor layer 229 provides a conductive path between the source electrode 225 and the drain electrode 227 and is formed on the organic insulating film 223 between the source electrode 225 and the drain electrode 227. The organic semiconductor layer 229 can be formed of pentacene, polyacetylene, polyaniline, or a derivative of these materials.

The passivation layer 231 seals the thin film structures that are beneath the inner side of the passivation layer 231 to prevent the gate electrode 221, the source electrode 225, and the drain electrode 227 from oxidizing or corroding and to prevent the organic insulating film 223 and the organic semiconductor layer 229 from degrading due to a reaction with oxygen or moisture. The passivation layer 231 has a structure in which barrier layers 231a and buffer layers 231b are alternately stacked. The barrier layers 231a block a reaction between external harmful materials and the inner thin film structures (including the gate electrode 221, the source electrode 225, the drain electrode 227, and the organic semiconductor layer 229). The buffer layers 231b prevent the brittlely damage of the barrier layers 231a that are weak, and provide a better condition for forming the barrier layer 213a so that the passivation layer 231 can be formed to be more than a predetermined thickness. The barrier layers 231a can be formed of an activated metal oxynitride, and the buffer layers 231b can be formed of a polymer organic material. The activated metal oxynitride is a compound in a state that an oxygen atom or a nitrogen atom lacks from a stable composed composition. The activated metal oxynitride, while it stabilizes on its own, prevents harmful components, such as oxygen or nitrogen, from penetrating into the organic electronic device through a reaction with the harmful components. The buffer layers 231b can be formed of a polymer organic material, such as polyurea, polyimide, polyamide that can be vapor deposition polymerized. The buffer layers 231b can also be formed of various polymer organic materials that can be polymerized by conventional heating, electromagnetic induced heating, laser or a heat bar, or ultrasonic friction.

An additional passivation layer 232 can be formed on a lower surface of the insulating substrate 210. The passivation layer 232 is not an essential element in the present invention, but can be implemented together with the passivation layer 231 covering the organic semiconductor layer 229 to obtain maximal blockage from the penetration of the impurities. The passivation layer 232 on the lower surface of the insulating substrate 210 can also be formed in a structure in which a plurality of barrier layers 232a and buffer layers 232b are alternately stacked, and thus, the descriptions thereof have not been repeated.

According to the present invention, an organic electronic device is not sealed in a can but is sealed with multiple passivation layers, thereby providing a thin and light-weight organic electronic device. In particular, harmful materials that can penetrate into the organic light emitting device can be effectively blocked since the passivation layer includes an activated metal oxynitride. Accordingly, a formation of dark points that decrease the display function ability and reduce luminance is substantially prevented.

While the present invention has been particularly shown and described with reference to exemplary embodiments thereof, it will be understood by those of ordinary skill in the art that various modifications in form and detail may be made therein without departing from the spirit and scope of the present invention as defined by the following claims.

What is claimed is:

1. An organic light emitting device comprising:
an insulating substrate;
a light emitting unit arranged on the insulating substrate and including a first electrode layer to inject holes, a second electrode layer inject electrons, and an active layer interposed between the first and second electrode layers to emit light by recombining the holes and electrons; and
a passivation layer including a plurality of alternately arranged barrier layers and buffer layers to seal the light emitting unit from an external atmosphere, each barrier layer including at least one material selected from a group consisting of an activated metal oxide, an activated metal nitride, or an activated metal oxynitride, and each buffer layer including either a polymer organic material or small molecule organic material.

2. The organic light emitting device of claim 1, wherein the activated metal oxide comprises a metal oxide in an activated unstable state derived from a stable metal oxide due to a deficiency in oxygen atoms.

3. The organic light emitting device of claim 1, wherein the activated metal nitride comprises a metal nitride in an activated unstable state derived from a stable metal nitride due to a deficiency in nitrogen atoms.

4. The organic light emitting device of claim 1, wherein the activated metal oxynitride comprises a metal oxynitride in an activated unstable state derived from a stable metal oxynitride due to a deficiency in oxygen and/or nitrogen atoms.

5. The organic light emitting device of claim 1, wherein the activated metal oxide comprises an oxide selected from a group consisting of Al₂O_{X}(1<X<3), BaO_{X}(0<X<1), In₂O_{X}(1<X<3), TiO_{X}(1<X<2), MgO_{X}(0<X<1), GeO_{X}(0<X<1), CaO_{X}(0<X<2), SrO_{X}(0<X<1), Y₂O_{X}(0<X<3), HfO_{X}(0<X<2), ZrO_{X}(0<X<2), MoO_{X}(0<X<3), and V₂O_{X}(0<X<5).

6. The organic light emitting device of claim 1, wherein the activated metal nitride comprises either AlN_{X}(0<X<1) or GaN_{X}(0<X<1).

7. The organic light emitting device of claim 1, wherein the activated metal oxynitride comprises SiO_{X}N_{Y}(0<X<2)(0<Y<2).

8. The organic light emitting device of claim 1, wherein each buffer layer is formed by either a vapor deposition polymerization method or vapor deposition method.

9. The organic light emitting device of claim 8, wherein each buffer layer comprises a small molecule organic material or a polymer organic material selected from a group consisting of polyurea, polyimide, and polyamide.

10. The organic light emitting device of claim 1, further comprising an additional passivation layer arranged on a lower surface of the insulating substrate.

11. An organic electronic device comprising:
an insulating substrate;
a plurality of electrodes arranged on the insulating substrate;
a conductive path including an organic semiconductor layer arranged across at least a portion of the plurality of electrodes; and
a passivation layer including a plurality of alternately arranged barrier layers and buffer layers to seal the organic semiconductor layer from an external atmosphere, each barrier layer including at least one material selected from a group consisting of an activated metal oxide, an activated metal nitride, or an activated metal oxynitride, and each buffer layer including a polymer organic material.

12. The organic electronic device of claim 11, wherein a gate electrode, an organic insulating film covering the gate electrode, and a source electrode and a drain electrode arranged on the organic insulating film are sequentially arranged on the insulating substrate, and wherein the organic semiconductor layer is arranged across the source electrode and the drain electrode and a portion of the organic insulating film.

13. The organic electronic device of claim 11, wherein the activated metal oxide comprises a metal oxide in an activated unstable state derived from a stable metal oxide due to a deficiency in oxygen atoms.

14. The organic electronic device of claim 11, wherein the activated metal nitride comprises a metal nitride in an activated unstable state derived from a stable metal nitride due to a deficiency in nitrogen atoms.

15. The organic electronic device of claim 11, wherein the activated metal oxynitride comprises a metal oxynitride in an activated unstable state derived from a stable metal oxynitride due to a deficiency in oxygen and/or nitrogen atoms.

16. The organic electronic device of claim 11, wherein the activated metal oxide comprises an oxide selected from a group consisting of Al₂O_{X}(1<X<3), BaO_{X}(0<X<1), In₂O_{X}(1<X<3), TiO_{X}(1<X<2), MgO_{X}(0<X<1), GeO_{X}(0<X<1), CaO_{X}(0<X<2), SrO_{X}(0<X<1), Y₂O_{X}(0<x<3), HfO_{X}(0<X<2), ZrO_{X}(0<X<2), MoO_{X}(0<X<3), and V₂O_{X}(0<X<5).

17. The organic electronic device of claim 11, wherein the activated metal nitride comprises either AlN_{X}(0<X<1) or GaN_{X}(0<X<1).

18. The organic electronic device of claim 11, wherein the activated metal oxynitride comprises SiO_{X}N_{Y}(0<X<2)(0<Y<2).

19. The organic electronic device of claim 11, wherein each buffer layer is formed by a vapor deposition polymerization method or vapor deposition method.

20. The organic electronic device of claim 19, wherein each buffer layer comprises a small molecule organic material or a polymer organic material selected from a group consisting of polyurea, polyimide, and polyamide.

21. The organic electronic device of claim 11, further comprising an additional passivation layer arranged on a lower surface of the insulating substrate.
